(19) United States
(12) Patent Application Publication
(10) Pub. No.: US 2004/0095736 A1
(43) Pub. Date: May 20, 2004

(54) Multi-chip package having increased reliabilty

(75) Inventors: Yun-Ho Choi, Suwon-city (KR); Kyung-Ho Kim, Suwon-city (KR)

Correspondence Address: Steven M. Mills, MILLS & ONELLE LLP, Suite 605, Eleven Beacon Street, Boston, MA, 02108, US

(73) Assignee: Samsung Electronics Co., Ltd.

(21) Appl. No.: 10/714,801

(22) Filed: Nov. 17, 2003

(30) Foreign Application Priority Data
Nov. 18, 2002 (KR) 02-71528

(51) Int. Cl. H05K 1/11

(52) U.S. Cl. 361/803

(57) ABSTRACT

A stack type multi-chip package with an increased reliability is provided. The stack type multi-chip package comprises a first semiconductor chip which shows good results when tested for reliability after being assembled at the package level, at least one second semiconductor chip which is in the wafer level and is stacked on the first semiconductor chip via stacking means, a first connecting unit for electrically connecting the first semiconductor chip to an external system, and a second connecting unit for electrically connecting the second semiconductor chip to the external system. The first connecting unit is different from the second connecting unit. Since the stack type multi-chip package comprises the semiconductor chip which shows good results when tested for reliability after being assembled at the package level, the reliability of the stack type multi-chip package can be effectively increased.

### BACKGROUND OF THE INVENTION

This application claims the priority of Korean Patent Application No. 2002-71528 filed on Nov. 18, 2002, in the Korean Intellectual Property Office, the contents of which are incorporated herein in their entirety by reference.

1. Field of the Invention

The present invention relates to a stack type multi-chip package, and more particularly, to a stack type multi-chip package including a semiconductor chip which is stacked on a lowermost layer of the package and is assembled at the package level.

2. Description of the Related Art

Multi-chip package (MCP) technology is a packaging technology capable of greatly reducing the size of a packaged product by incorporating two or more semiconductor chips into a single package. Since a trend toward small and light information devices, such as a cellular phones, has arisen, the importance of MCP has greatly increased. Recently, the MCP technology has been expanded from an MCP technology capable of stacking semiconductor chips of the same kind to a hybrid MCP technology capable of stacking semiconductor chips of different kinds.

FIG. 1 is a cross-sectional view of a stack type MCP 100 according to prior art. The stack type multi-chip package 100 includes a plurality of semiconductor chips 110, 120, and 130, an adhesive 140, a plurality of bonding wires 1.50, 160, and 170, a plastic molding compound 180, and a printed circuit board (PCB) 190 for a multi-chip package.

The semiconductor chips 110, 120, and 130 are different kinds of chips, and are of a good die (bare die) showing good results after conducting tests at the wafer level. The bare die may be referred to as bare chips. For example, a non-volatile memory (NVM) such as a flash memory, a mobile Dynamic Random Access Memory (DRAM), and a pseudo Static Random Access Memory (SRAM) such as an unit-transistor RAM (utRAM) may be stacked in the order as the first, second, and third semiconductor chips 110, 120, and 130.

The plurality of bonding wires 150, 160, and 170 electrically connect the semiconductor chips 110, 120, and 130 to the PCB 190, respectively. A plurality of solder balls 191 included in the PCB 190 electrically connect the stack type multi-chip package 100 to an external system (not shown).

The plastic molding compound 180 fastens the semiconductor chips 110, 120, and 130 and protects the semiconductor chips 110, 120, and 130 from the external environment.

Since the semiconductor chips 110, 120, and 130 of different kinds are stacked and are assembled in the stack type MCP 100 according to prior art, a finished product of the stack type MCP 100 may be considered as a defective product when tested for reliability by problems caused by the semiconductor chip 110 (for example, flash memory) having relatively low reliability among the plurality of semiconductor chips 110, 120, and 130. As a result, the productivity of the stack type MCP is reduced, and thus, the cost of the stack type MCP can increase.

Further, since the semiconductor chips having bonding pads of different structures are stacked and are assembled in the stack type MCP 100 according to prior art, a defective rate of the stack type MCP 100 is increased when the bonding wires are wire-bonded to the bonding pads of the semiconductor chips, thereby reducing the reliability of the stack type MCP.

### SUMMARY OF THE INVENTION

The present invention provides a stack type multi-chip package in which a semiconductor chip of relatively low reliability among a plurality of semiconductor chips is assembled at the package level and the rest of the semiconductor chips are stacked on the semiconductor chip of relatively low reliability in a perpendicular direction.

According to an aspect of the present invention, there is provided a stack type multi-chip package comprising a first semiconductor chip which shows good results when tested for reliability after being assembled at the package level; at least one second semiconductor chip which is in a wafer level configuration and is stacked on the first semiconductor chip via stacking means; a first connecting unit for electrically connecting the first semiconductor chip to an external system; and a second connecting unit for electrically connecting the second semiconductor chip to the external system, wherein the first connecting unit is different from the second connecting unit.

In one embodiment, the stack type multi-chip package comprises a printed circuit board for the multi-chip package, which includes bonding pads to which the first connecting unit and the second connecting unit are connected and pins for connecting the bonding pads to the external system.

In one embodiment, the stack type multi-chip package comprises a molding compound for fastening the first and second semiconductor chips and protecting the first and second semiconductor chips from the external environment.

In one embodiment, the stacking means are an adhesive, and the package type of the first semiconductor chip is a Fine Ball Grid Array (FBGA), a Wafer-Level Chip Size Package (W-CSP), a Thin Quad Flat package (TQFP), a Super Thin Small Outline Package (STSOP), or a Ball Grid Array (BGA).

In one embodiment, the first connecting unit is a solder bump for connecting solder balls of the FBGA, the W-CSP, and the BGA or pins of the TQFP and the STSOP to the bonding pads of the printed circuit board, and the second connecting unit is bonding wires for connecting pads of the second semiconductor chip to the bonding pads of the printed circuit board.

In one embodiment, the package type of the printed circuit board is a BGA or a TQFP.

It is preferable that in a case where the package type of the first semiconductor chip is the FBGA, the W-CSP, or the BGA, the first semiconductor chip and the second semiconductor chip are stacked via the adhesive such that their back surfaces face each other.

It is preferable that in a case where the package type of the first semiconductor chip is the TQFP or the STSOP, one surface, on which pads of the first semiconductor chip are disposed, faces and is stacked on the back surface of the second semiconductor chip via the adhesive.

Since the stack type multi-chip package comprises a semiconductor chip which shows good results when tested for reliability after being assembled at the package level, the reliability of the stack type multi-chip package can be effectively increased. Thus, since a defective rate of the stack type multi-chip package is reduced, the manufacturing cost of the stack type multi-chip package can be reduced.

### BRIEF DESCRIPTION OF THE DRAWINGS

The foregoing and other objects, features and advantages of the invention will be apparent from the more particular description of a preferred embodiment of the invention, as illustrated in the accompanying drawings in which like reference characters refer to the same parts throughout the different views. The drawings are not necessarily to scale, emphasis instead being placed upon illustrating the principles of the invention.

FIG. 1 is a cross-sectional view of a stack type multi-chip package according to prior art.

FIG. 2 is a cross-sectional view of a stack type multi-chip package according to a first embodiment of the present invention.

FIG. 3 is a plan view of a printed circuit board for the multi-chip package shown in FIG. 2.

FIG. 4 is a cross-sectional view of a stack type multi-chip package according to a second embodiment of the present invention.

FIG. 5 is a plan view of a printed circuit board for the multi-chip package shown in FIG. 4.

FIG. 6 is a cross-sectional view of a stack type multi-chip package according to a third embodiment of the present invention.

FIG. 7 is a plan view of a printed circuit board for the multi-chip package shown in FIG. 6.

FIG. 8 is a cross-sectional view of a stack type multi-chip package according to a fourth embodiment of the present invention.

FIG. 9 is a plan view of a printed circuit board for the multi-chip package shown in FIG. 8.

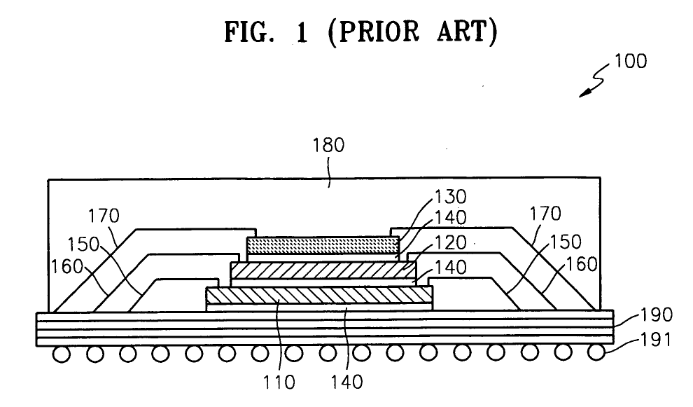

### DETAILED DESCRIPTION OF THE INVENTION

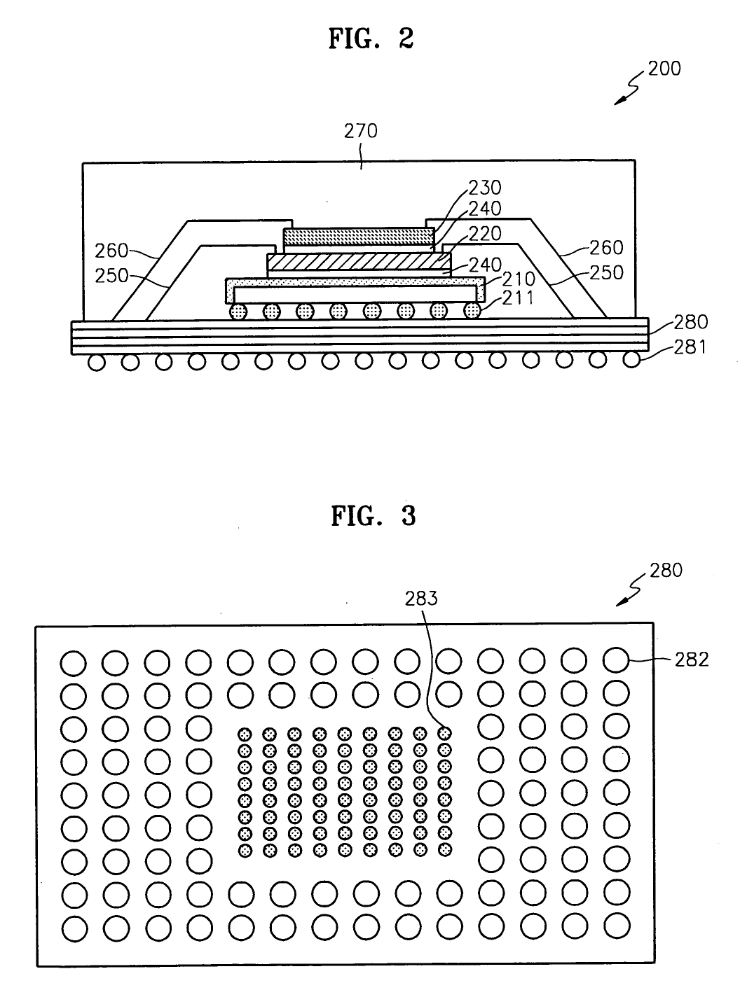

FIG. 2 is a cross-sectional view of a stack type multi-chip package (MCP) 200 according to a first embodiment of the present invention.

As shown in FIG. 2, the stack type MCP 200 includes a first semiconductor chip 210, a second semiconductor chip 220, a third semiconductor chip 230, a stacking means such as adhesive 240, bonding wires 250 and 260, a molding compound 270, and a printed circuit board (PCB) 280 for the multi-chip package.

The semiconductor chips 210, 220, and 230 are each a different kind of chip. For example, a non-volatile memory (NVM) such as a flash memory, a mobile Dynamic Random Access Memory (DRAM), and a pseudo a Static Random Access Memory (SRAM) such as a unit-transistor RAM (utRAM) may be stacked in the order as the first, second, and third semiconductor chips 210, 220, and 230. The reliability of the flash memory is weaker than that of the semiconductor chips of a different type.

The reliability tests conducted after the first semiconductor chip 210 was assembled at the package level showed good results. The first semiconductor chip 210 may be a semiconductor chip such as a flash memory having relatively high defective rate. Further, it is preferable that the package type of the first semiconductor chip 210 is a Fine Ball Grid Array (FBGA) or a Wafer-Level Chip Size Package (W-CSP) included in a Chip Scale Package (CSP). The CSP is referred to as a micro-package whose size is similar to the size of the semiconductor chip. The first semiconductor chip 210 is electrically connected to the PCB 280 via solder balls 211.

A variety of tests conducted at the wafer level showed that the second semiconductor chip 220 was obtained from a good die (bare chip) showing good results. The second semiconductor chip 220 is stacked on the first semiconductor chip 210 in a perpendicular direction via, for example, the adhesive 240. Specifically, the first semiconductor chip 210 and the second semiconductor chip 220 are stacked via the adhesive 240 such that their back surfaces face each other. Here, the back surface of the semiconductor chip is referred to as an opposite surface of a surface on which pads of the semiconductor chip are disposed. Pads (not shown) of the second semiconductor chip 220 are electrically connected to the PCB 280 via the bonding wires 250.

A variety of tests conducted at the wafer level showed that the third semiconductor chip 230 was obtained from a good die (bare chip) showing good results. The third semiconductor chip 230 is stacked on the second semiconductor chip 220 in a perpendicular direction via, for example, the adhesive 240. Pads (not shown) of the third semiconductor chip 230 are electrically connected to the PCB 280 via the bonding wires 260.

The molding compound 270 fastens the stacked semiconductor chips 210, 220, and 230, and protects the stacked semiconductor chips 210, 220, and 230 from the external environment.

The stacked semiconductor chips 210, 220, and 230 are electrically and mutually connected on the PCB 280. The stacked semiconductor chips 210, 220, and 230 that are mutually connected are electrically connected to an external system (not shown) via solder balls 281 of the PCB 280 it is preferable that the package type of the PCB 280 is a Ball Grid Array (BGA).

Thus, since the semiconductor chip of relatively low reliability among the plurality of semiconductor chips is assembled at the package level and the rest of the semiconductor chips are stacked on the semiconductor chip of relatively low reliability in the stack type MCP 200 according to the first embodiment of the present invention, the reliability of the stack type MCP 200 can be efficiently increased. Further, the defective rate of the stack type MCP 200 is greatly reduced by the increased reliability of the stack type MCP 200, thereby greatly reducing the manufacturing cost of the stack type MCP 200.

FIG. 3 is a plan view of the PCB 280 for the multi-chip package shown in FIG. 2. As shown in FIG. 3, a plurality of first bonding pads 282 and a plurality of second bonding pads 283 are disposed on the PCB 280. The bonding wires 250 and 260 of the second and third semiconductor chips 220 and 230 shown in FIG. 2 are connected to the first bonding pads 282. The solder balls 211 of the first semiconductor chip 210 shown in FIG. 2 are connected to the second bonding pads 283 via a solder bump (not shown).

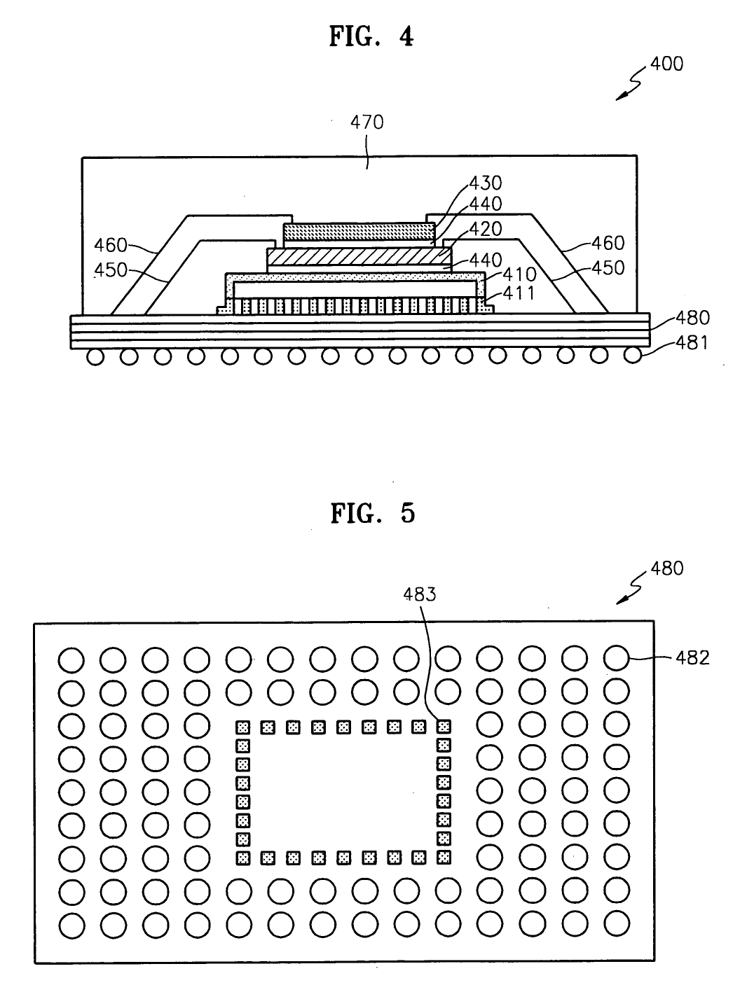

FIG. 4 is a cross-sectional view of a stack type MCP 400 according to a second embodiment of the present invention.

As shown in FIG. 4, the stack type MCP 400 includes a first semiconductor chip 410, a second semiconductor chip 420, a third semiconductor chip 430, a stacking means such as adhesive 440, bonding wires 450 and 460, a molding compound 470, and a PCB 480 for the multi-chip package.

The reliability test conducted after the first semiconductor chip 410 is assembled at the package level showed good results. The first semiconductor chip 410 may be a semiconductor chip such as a flash memory having relatively high defective rate. Further, it is preferable that the package type of the first semiconductor chip 410 is a Thin Quad Flat package (TQFP) or a Super Thin Small Outline Package (STSOP). Pins 411 of the first semiconductor chip 410 are electrically connected to the PCB 480 via a solder bump (not shown).

A variety of tests conducted at the wafer level showed that the second semiconductor chip 420 was obtained from a good die (bare chip) showing good results. The second semiconductor chip 420 is stacked on the first semiconductor chip 410 in a perpendicular direction via, for example, the adhesive 440. That is, one surface (that is, upper surface), on which pads (not shown) of the first semiconductor chip 410 are disposed, faces and is stacked on a back surface of the second semiconductor chip 420 via the adhesive 440. Here, the back surface of the semiconductor chip is referred to as an opposite surface of a surface on which pads of the semiconductor chip are disposed. Pads (not shown) of the second semiconductor chip 420 are electrically connected to the PCB 480 via the bonding wires 450.

A variety of tests conducted at the wafer level showed that the third semiconductor chip 430 was obtained from a good die (bare chip) showing good results. The third semiconductor chip 430 is stacked on the second semiconductor chip 420 in a perpendicular direction via, for example, the adhesive 440. Pads (not shown) of the third semiconductor chip 430 are electrically connected to the PCB 480 via the bonding wires 460.

The molding compound 470 fastens the stacked semiconductor chips 410, 420, and 430 and protects the stacked semiconductor chips 410, 420, and 430 from the external environment.

The stacked semiconductor chips 410, 420, and 430 are electrically and mutually connected on the PCB 480. The stacked semiconductor chips 410, 420, and 430 that are mutually connected are electrically connected to an external system (not shown) via solder balls 481 of the PCB 480. It is preferable that the package type of the PCB 480 is a BGA.

FIG. 5 is a plan view of the PCB 480 for the multi-chip package shown in FIG. 4. As shown in FIG. 5, a plurality of first bonding pads 482 and a plurality of second bonding pads 483 are disposed on the PCB 480. The bonding wires 450 and 460 of the second and third semiconductor chips 420 and 430 shown in FIG. 4 are connected to the first bonding pads 482. The pins 411 of the first semiconductor chip 410 shown in FIG. 4 are connected to the second bonding pads 483 via a solder bump (not shown).

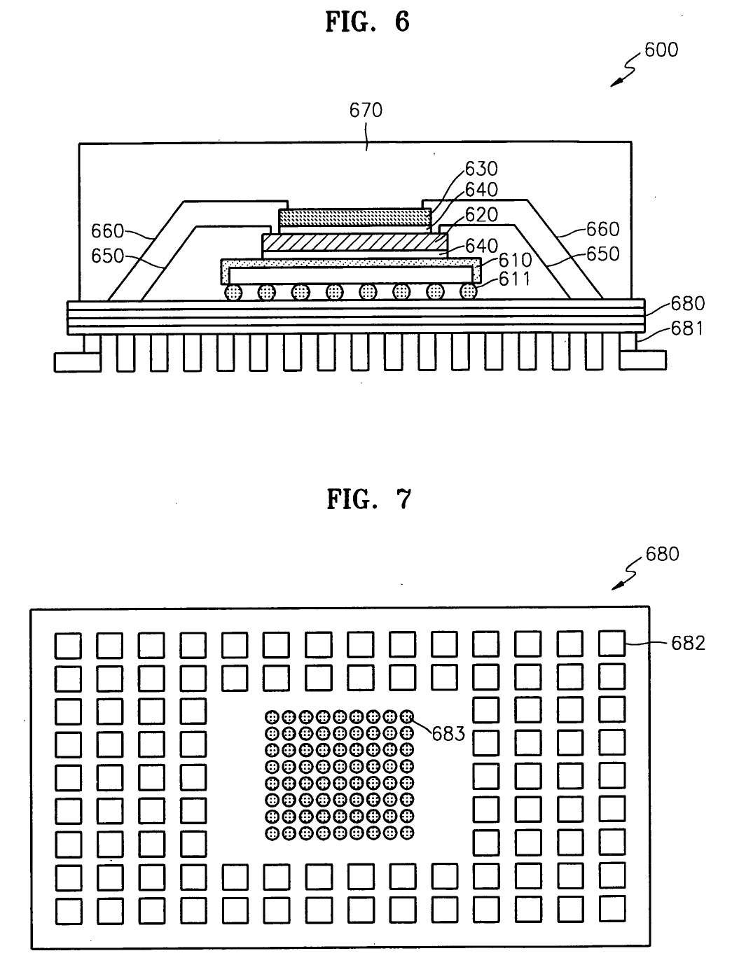

FIG. 6 is a cross-sectional view of a stack type MCP 600 according to a third embodiment of the present invention.

As shown in FIG. 6, the stack type MCP 600 includes a first semiconductor chip 610, a second semiconductor chip 620, a third semiconductor chip 630, a stacking means such as adhesive 640, bonding wires 650 and 660, a molding compound 670, and a PCB 680 for the multi-chip package.

The reliability test conducted after the first semiconductor chip 610 is assembled at the wafer level showed good results. The first semiconductor chip 610 may be a semiconductor chip such as a flash memory having relatively high defective rate. Further, it is preferable that the package type of the first semiconductor chip 610 is a BGA. The first semiconductor chip 610 is electrically connected to the PCB 680 via solder balls 611.

A variety of tests conducted at the wafer level showed that the second semiconductor chip 620 is obtained from a good die (bare chip) showing good results. The second semiconductor chip 620 is stacked on the first semiconductor chip 610 in a perpendicular direction via, for example, the adhesive 640. That is, the first semiconductor chip 610 and the second semiconductor chip 620 are stacked via the adhesive 640 such that their back surfaces face each other. Here, the back surface of the semiconductor chip is referred to as an opposite surface of a surface on which pads of the semiconductor chip are disposed. Pads (not shown) of the second semiconductor chip 620 are electrically connected to the PCB 680 via the bonding wires 650.

A variety of tests conducted at the wafer level showed that the third semiconductor chip 630 is obtained from a good die (bare chip) showing good results. The third semiconductor chip 630 is stacked on the second semiconductor chip 620 in a perpendicular direction via, for example, the adhesive 640. Pads (not shown) of the third semiconductor chip 630 are electrically connected to the PCB 680 via the bonding wires 660.

The molding compound 670 fastens the stacked semiconductor chips 610, 620, and 630 and protects the stacked semiconductor chips 610, 620, and 630 from the external environment.

The stacked semiconductor chips 610, 620, and 630 are electrically and mutually connected on the PCB 680. The stacked semiconductor chips 610, 620, and 630 that are mutually connected are electrically connected to an external system (not shown) via pins 681 of the PCB 680. It is preferable that the package type of the PCB 680 is a Quad Flat package (QFP).

FIG. 7 is a plan view of the PCB 680 for the multi-chip package shown in FIG. 6. As shown in FIG. 7, a plurality of first bonding pads 682 and a plurality of second bonding pads 683 are disposed on the PCB 680. The bonding wires 650 and 660 of the second and third semiconductor chips 620 and 630 shown in FIG. 6 are connected to the first bonding pads 682. The solder balls 611 of the first semiconductor chip 610 shown in FIG. 6 are connected to the second bonding pads 683 via a solder bump (not shown).

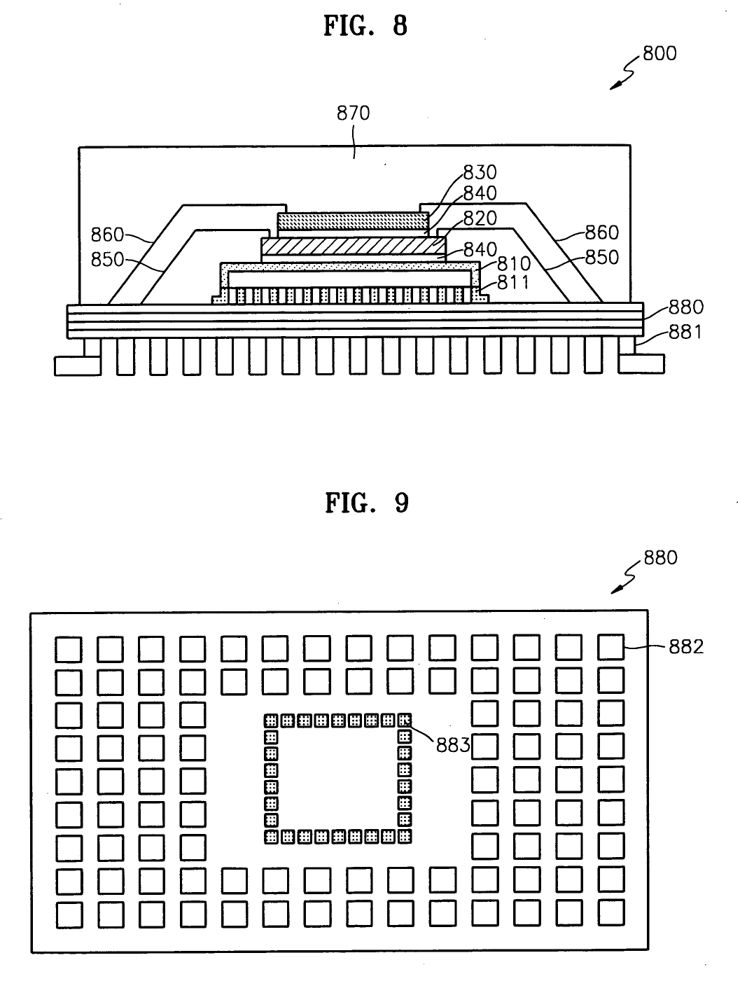

FIG. 8 is a cross-sectional view of a stack type MCP 800 according to a fourth embodiment of the present invention.

As shown in FIG. 8, the stack type MCP 800 includes a first semiconductor chip 810, a second semiconductor chip 820, a third semiconductor chip 830, a stacking means such as adhesive 840, bonding wires 850 and 860, a molding compound 870, and a PCB 880 for a multi-chip package.

The reliability test conducted after the first semiconductor chip 810 is assembled at the package level showed good results. The first semiconductor chip 810 may be a semiconductor chip such as a flash memory having relatively high defective rate. Further, it is preferable that the package type of the first semiconductor chip 810 is a TQFP or a STSOP. Pins 811 of the first semiconductor chip 810 are electrically connected to the PCB 880 via a solder bump (not shown).

A variety of tests conducted at the wafer level showed that the second semiconductor chip 820 was obtained from a good die (bare chip) showing good results. The second semiconductor chip 820 is stacked on the first semiconductor chip 810 in a perpendicular direction via, for example, the adhesive 840. That is, one surface (that is, upper surface), on which pads (not shown) of the first semiconductor chip 810 are disposed, faces and is stacked on a back surface of the second semiconductor chip 820 via the adhesive 840. Here, the back surface of the semiconductor chip is referred to as an opposite surface of a surface on which pads of the semiconductor chip are disposed. Pads (not shown) of the second semiconductor chip 820 are electrically connected to the PCB 880 via the bonding wires 850.

A variety of tests conducted at the Wafer level showed that the third semiconductor chip 830 was obtained from a good die (bare chip) showing good results. The third semiconductor chip 830 is stacked on the second semiconductor chip 820 in a perpendicular direction via, for example, the adhesive 840. Pads (not shown) of the third semiconductor chip 830 are electrically connected to the PCB 880 via the bonding wires 860.

The molding compound 870 fastens the stacked semiconductor chips 810, 820, and 830 and protects the stacked semiconductor chips 810, 820, and 830 from the external environment.

The stacked semiconductor chips 810, 820, and 830 are electrically and mutually connected on the PCB 880. The stacked semiconductor chips 810, 820, and 830 that are mutually connected are electrically connected to an external system (not shown) via pins 881 of the PCB 880. It is preferable that the package type of the PCB 880 is a TQFP.

FIG. 9 is a plan view of the PCB 880 for the multi-chip package shown in FIG. 8. As shown in FIG. 9, a plurality of first bonding pads 882 and a plurality of second bonding pads 883 are disposed on the PCB 880. The bonding wires 850 and 860 of the second and third semiconductor chips 820 and 830 shown in FIG. 8 are connected to the first bonding pads 882. The pins 811 of the first semiconductor chip 810 shown in FIG. 8 are connected to the second bonding pads 883 via a solder bump (not shown).

While the present invention has been particularly shown and described with reference to preferred embodiments thereof, it will be understood by those of ordinary skill in the art that various changes in form and details may be made therein without departing from the spirit and scope of the present invention as defined by the appended claims.

What is claimed is:

1. A stack type multi-chip package comprising:
a first semiconductor chip which shows good results when tested for reliability after being assembled at a package level;
at least one second semiconductor chip which is in a wafer level configuration and is stacked on the first semiconductor chip via stacking means;
a first connecting unit for electrically connecting the first semiconductor chip to an external system; and
a second connecting unit for electrically connecting the second semiconductor chip to the external system,
wherein the first connecting unit is different from the second connecting unit.

2. The stack type multi-chip package of claim 1, further comprising a printed circuit board for the multi-chip package, which includes bonding pads to which the first connecting unit and the second connecting unit are connected, and pins for connecting the bonding pads to the external system.

3. The stack type multi-chip package of claim 2, further comprising a molding compound for fastening the first and second semiconductor chips and protecting the first and second semiconductor chips from the external environment.

4. The stack type multi-chip package of claim 3, wherein the stacking means are an adhesive.

5. The stack type multi-chip package of claim 4, wherein the package type of the first semiconductor chip is a Fine Ball Grid Array (FBGA) or a Wafer-Level Chip Size Package (W-CSP).

6. The stack type multi-chip package of claim 5, wherein the first connecting unit is a solder bump for connecting solder balls of the FBGA or the W-CSP to the bonding pads of the printed circuit board,
the second connecting unit is bonding wires for connecting pads of the second semiconductor chip to the bonding pads of the printed circuit board.

7. The stack type multi-chip package of claim 6, wherein the package type of the printed circuit board is a Ball Grid Array (BGA).

8. The stack type multi-chip package of claim 7, wherein the first semiconductor chip and the second semiconductor chip are stacked via the adhesive such that their back surfaces face each other.

9. The stack type multi-chip package of claim 4, wherein the package type of the first semiconductor chip is a Thin Quad Flat package (TQFP) or a Super Thin Small Outline Package (STSOP).

10. The stack type multi-chip package of claim 9, wherein the first connecting unit is a solder bump for connecting pins of the TQFP or the STSOP to the bonding pads of the printed circuit board,
the second connecting unit is bonding wires for connecting pads of the second semiconductor chip to the bonding pads of the printed circuit board.

11. The stack type multi-chip package of claim 10, wherein the package type of the printed circuit board is a BGA.

12. The stack type multi-chip package of claim 10, wherein the package type of the printed circuit board is a TQFP.

13. The stack type multi-chip package of claim 11, wherein one surface, on which pads of the first semiconductor chip are disposed, faces and is stacked on a back surface of the second semiconductor chip via the adhesive.

14. The stack type multi-chip package of claim 12, wherein one surface, on which pads of the first semiconductor chip are disposed, faces and is stacked on a back surface of the second semiconductor chip via the adhesive.

15. The stack type multi-chip package of claim 4, wherein the package type of the first semiconductor chip is a BGA.

16. The stack type multi-chip package of claim 15, wherein the first connecting unit is a solder bump for connecting solder balls of the BGA to the bonding pads of the printed circuit board,
the second connecting unit is bonding wires for connecting pads of the second semiconductor chip to the bonding pads of the printed circuit board.

17. The stack type multi-chip package of claim 16, wherein the package type of the printed circuit board is a TQFP.

18. The stack type multi-chip package of claim 17, wherein the first semiconductor chip and the second semiconductor chip are stacked via the adhesive such that their back surfaces face each other.
